(19) United States
(12) Patent Application Publication
(10) Pub. No.: US 2026/0246345 A1
(43) Pub. Date: Aug. 20, 2026

(54) PERMANENT MAGNET AND VARIABLE FREQUENCY INTEGRATED MACHINE

(71) Applicant: QINGDAO CCS ELECTRIC CORPORATION, Shandong (CN)

(72) Inventors: HONGBO ZHANG, Shandong (CN); XUFENG YANG, Shandong (CN); BIN ZHAO, Shandong (CN); CHAONAN HUANG, Shandong (CN); ZHANGUANG JIANG, Shandong (CN); XIHUA WANG, Shandong (CN); RONGSHENG LU, Shandong (CN); WEN LUO, Shandong (CN)

(21) Appl. No.: 19/161,871

(22) PCT Filed: Dec. 10, 2024
(86) PCT No.: PCT/CN2024/138008

§ 371 Date: Sep. 3, 2025

(30) Foreign Application Priority Data
Dec. 27, 2023 (CN) 202311829540.6

(51) Int. Cl. H02K 11/33; B65G 23/22; H02K 5/22; H02K 11/27; H02P 27/06; H05K 7/20

(52) U.S. Cl. CPC H02K 11/33; H02K 5/225; H02K 11/27; H02P 27/06; H05K 7/20927; B65G 23/22; H02P 2207/05

(57) ABSTRACT

A permanent magnet and variable frequency integrated machine includes a variable-frequency drive (VFD) and a permanent magnet motor, where the permanent magnet motor extends forwards and backwards in an axial direction thereof, the VFD is integrated on a peripheral side of the permanent magnet motor, and a power supply and distribution apparatus, detachably connected to the VFD, is further provided on the peripheral side of the permanent magnet motor, and configured to provide electric energy for an electric device. The permanent magnet and variable frequency integrated machine adopts the design concept of integrating a VFD, a power supply and distribution apparatus and a permanent magnet motor, which can satisfy the application requirement for a small volume. In addition, modular designs of the VFD and the power supply and distribution apparatus are implemented, thereby facilitating on-site replacement and maintenance.

### CROSS REFERENCE TO RELATED APPLICATIONS AND CLAIM OF PRIORITY

This application claims benefit under 35 U.S.C. 119, 120, 121, or 365(c), and is a National Stage entry from International Application No. PCT/CN2024/138008 filed on Dec. 10, 2024, which claims priority to the benefit of Chinese Patent Application No. 202311829540.6 filed on Dec. 27, 2023 in the China Intellectual Property Office, the entire contents of which are incorporated herein by reference.

### BACKGROUND

### 1. Technical Field

The present disclosure generally relates to the technical field of power supply and distribution for mines. More specifically, the present disclosure relates to a permanent magnet and variable frequency integrated machine.

### 2. Background of the Invention

The drive modes of belt conveyors in China mainly go through an evolution process from “mobile substation plus double-speed motor plus reducer”, “mobile substation plus motor plus hydraulic coupler plus reducer”, “mobile substation plus motor plus controlled start transmission (CST)” to “mobile substation plus variable-frequency drive (VFD) plus motor plus reducer”. The current mainstream drive mode is “mobile substation plus VFD plus asynchronous motor plus reducer”, which has the advantages of small impact on machinery and electrical systems during starting, automatic speed regulation and the like, but still has the problems of large size, low power factor, severe electromagnetic interference and mechanical abrasion, difficulty in maintenance and the like. In recent years, mobile substation for mining plus VFD plus permanent magnet direct drive motor has gradually become a main solution for those problems. However, with the further increasing requirements for green coal mining nationwide, and the problems of high incoming line voltage level, low system efficiency, narrow installation space, frequent relocation and face changes of an entry belt conveyor, complex electromagnetic environment with severe interference and the like of a coal mine belt conveyor, the existing technology is difficult to meet the requirements.

In view of this, there is an urgent need fora scheme of a permanent magnet and variable frequency integrated machine which can solve the problems of high incoming line voltage level, difficulty in maintenance, narrow installation space, and the like.

### SUMMARY

To address at least one or more of the above technical problems, the present disclosure proposes a scheme of a permanent magnet and variable frequency integrated machine.

The present disclosure provides a permanent magnet and variable frequency integrated machine, including a variable-frequency drive (VFD) and a permanent magnet motor, wherein the permanent magnet motor extends forwards and backwards in an axial direction thereof, the VFD is integrated on a peripheral side of the permanent magnet motor, and a power supply and distribution apparatus, detachably connected to the VFD, is further provided on the peripheral side of the permanent magnet motor, and configured to provide electric energy for an electric device.

In some embodiments, the power supply and distribution apparatus includes a box body and ports in the box body, the ports including an input port, a direct output port and an indirect output port, wherein the input port is connected to a power connection; the direct output port is electrically connected to the input port and configured to directly output an input power; and the indirect output port is electrically connected to the input port and connected to the permanent magnet motor through the VFD.

In some embodiments, the power supply and distribution apparatus is provided with multiple sets of transformers electrically connected to the input port and other electric devices to convert a voltage of the input power into voltages for the other electric devices.

In some embodiments, the power supply and distribution apparatus is provided with a disconnector switch and a vacuum contactor, and the multiple sets of transformers and the indirect output port are connected to the input port through the disconnector switch to disconnect a fault circuit.

In some embodiments, the power supply and distribution apparatus is provided with a control unit configured to control a current at each voltage to enter the other electric devices.

In some embodiments, the power supply and distribution apparatus further includes a plurality of output ports, via which the multiple sets of transformers are connected to the other electric devices.

In some embodiments, the VFD includes a VFD module, a control module, and a protection module, wherein the VFD module is connected to the permanent magnet motor and configured to convert a frequency of the input power into different frequencies to be output; the control module disposed in an upper layer of the VFD module to control the VFD module; and the protection module includes a fuse, a reactor and a contactor, and is connected to the input power or the power supply and distribution apparatus, and configured to protect the VFD module.

In some embodiments, the VFD module is disposed on a water-cooling heat dissipation plate with an S-shaped heat dissipation water channel.

In some embodiments, the VFD module includes a power module and a filter capacitor module connected by a laminated busbar to reduce parasitic inductance.

In some embodiments, the power module includes a rectifier module and an inverter module electrically connected with each other, the rectifier module is connected to the protection module, and the inverter module is connected to the permanent magnet motor.

In some embodiments, the power module includes an insulation frame arranged around for isolating a high-voltage power supply and enabling uniform heat dissipation of the power module.

In some embodiments, the VFD includes at least one standby line inlet port disposed on a sidewall of the VFD, connected to the protection module and configured to connect the input power.

With the permanent magnet and variable frequency integrated machine described above, the embodiments of the present disclosure adopt the design concept of integrating a VFD, a power supply and distribution apparatus and a permanent magnet synchronous motor, and enables modular designs of the VFD unit and the power supply and distribution apparatus, thereby facilitating on-site replacement and maintenance. The power supply and distribution apparatus may provide power distribution for other electric devices in the belt conveyor system, thereby simplifying the on-site power supply and distribution system. Due to possible on-site installation space limitations and usage requirements, the power supply and distribution apparatus may be selectively assembled, disassembled, or installed on a different side depending on different application scenarios to facilitate on-site use. Furthermore, in some embodiments, the box body provided with ports of the power supply and distribution apparatus enables fast assembly of electric devices and thus fast assembly of the power supply and distribution apparatus, so that power can be supplied to surrounding electric devices in a short time and the on-site assembly procedure is simplified, and even an operator who does not know the power supply and distribution apparatus can assemble and use the apparatus quickly, thereby improving the working efficiency. Furthermore, in some embodiments, by providing multiple sets of transformers in the power supply and distribution apparatus, the voltage of the input power can be converted into various voltages for electric devices to supply power to surrounding electric devices, so that the mobile substation can be omitted and the assembly procedure is simplified. Furthermore, in some embodiments, the power supply and distribution apparatus with a disconnector switch and a vacuum contactor can ensure safety of the operator while protecting the power supply and distribution apparatus, where the circuit can be manually cut off when electricity is not needed, and the circuit can be automatically cut off in case of a failure, thereby providing double isolation and protection and improving the safety performance. Furthermore, in some embodiments, the modular design of the VFD can facilitate convenient maintain or overhaul of the VFD. Furthermore, in some embodiments, the VFD module on the water-cooling heat dissipation plate can reduce the temperature of the VFD and ensure normal operation of the VFD. Furthermore, in some embodiments, by providing at least one standby line inlet port on the VFD and connected to the input power or an output power supply of the power supply and distribution apparatus, the permanent magnet and variable frequency integrated machine can be directly connected to an external power supply to enable flexible assembly of the power supply and distribution apparatus, and the use of other power supply and distribution apparatuses and the permanent magnet and variable frequency integrated machine will not be influenced even if one of the power supply and distribution apparatuses is failed.

### BRIEF DESCRIPTION OF THE DRAWINGS

The above and other objectives, features and advantages of the exemplary implementations of the present disclosure will become readily apparent from the following detailed description, which proceeds with reference to the accompanying drawings. In the accompanying drawings, several implementations of the present disclosure are illustrated by way of example but not limitation, and like or corresponding reference numerals indicate like or corresponding parts, in which:

FIG. 1 shows a schematic overall structural diagram of a permanent magnet and variable frequency integrated machine according to an embodiment of the present disclosure;

FIG. 2 shows a schematic overall structural diagram of a power supply and distribution apparatus according to an embodiment of the present disclosure;

FIG. 3 shows a structural block diagram of port connection in a power supply and distribution apparatus according to some embodiments of the present disclosure;

FIG. 4 shows a structural block diagram of a belt conveyor system according to some embodiments of the present disclosure;

FIG. 5 shows a block diagram of internal structures of a power supply and distribution apparatus according to some embodiments of the present disclosure;

FIG. 6 shows a schematic diagram of internal structures of a power supply and distribution apparatus according to some embodiments of the present disclosure;

FIG. 7 shows a schematic diagram of an A-A structure in a power supply and distribution apparatus according to some embodiments of the present disclosure;

FIG. 8 shows a schematic overall structural diagram of another permanent magnet and variable frequency integrated machine according to some embodiments of the present disclosure;

FIG. 9 shows a schematic structural diagram of a VFD box according to some embodiments of the present disclosure;

FIG. 10 shows a schematic diagram of internal structures of a protection box according to some embodiments of the present disclosure;

FIG. 11 shows a schematic diagram of an A-A structure of a VFD box according to some embodiments of the present disclosure;

FIG. 12 shows a schematic diagram of a B-B structure of a VFD box according to some embodiments of the present disclosure; and

FIG. 13 shows a schematic structural diagram of a water-cooling heat dissipation plate according to some embodiments of the present disclosure.

### DETAIL DESCRIPTION OF THE INVENTION

The technical solutions in the embodiments of the present disclosure will be clearly and completely described below with reference to the accompanying drawings in the embodiments of the present disclosure. Apparently, the described embodiments are only part, but not all, of the embodiments of the present disclosure. All other embodiments, which can be derived by those skilled in the art from the embodiments of the present disclosure without making any creative effort, shall fall within the protection scope of the present disclosure.

It will be understood that the terms “comprise” and “include”, when used in the description and claims of the present disclosure, specify the presence of the stated features, integers, steps, operations, elements, and/or components, but do not preclude the presence or addition of one or more other features, integers, steps, operations, elements, components, and/or groups thereof.

It is also to be understood that the terminology used in the description of the disclosure herein is for the purpose of describing particular embodiments only, and is not intended to be limiting of the disclosure. As used in the specification and claims of the disclosure, the singular forms “a”, “an” and “the” are intended to include the plural forms as well, unless the context clearly indicates otherwise. It should be further understood that the term “and/or” as used in the description and claims of the disclosure refers to any and all possible combinations of one or more of the associated listed items and includes such combinations.

As used in this specification and claims, the term “if” may be interpreted as “when” or “once” or “in response to determining” or “in response to detecting” depending on the context. Similarly, the phrase “if it is determined” or “if [the described condition or event] is detected” may be interpreted contextually as meaning “upon determining” or “in response to determining” or “upon detecting [the described condition or event]” or “in response to detecting [the described condition or event]”.

Specific implementations of the present disclosure will be described in detail below with reference to the accompanying drawings.

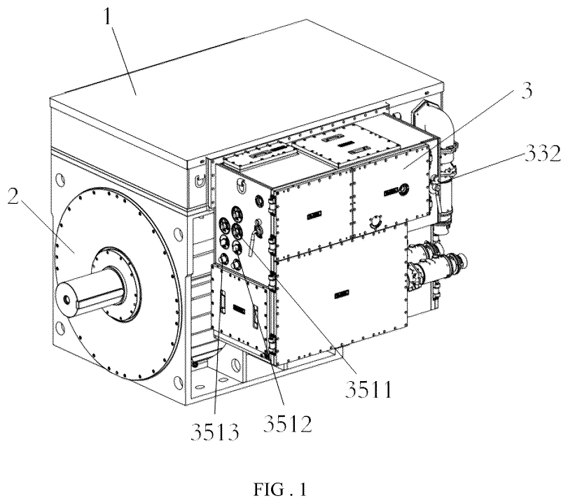

The present disclosure provides a permanent magnet and variable frequency integrated machine which, as shown in FIG. 1, includes a variable-frequency drive (VFD) 1 and a permanent magnet motor 2. The permanent magnet motor 2 extends forwards and backwards in an axial direction thereof, and the VFD 1 is integrated on a peripheral side of the permanent magnet motor 2. A power supply and distribution apparatus 3, detachably connected to the VFD 1, is further provided on the peripheral side of the permanent magnet motor 2, and configured to provide electric energy for an electric device.

Specifically, the VFD 1 is integrated on a peripheral side of the permanent magnet motor 2 and adopts a cuboid structure, so that internal structures of the VFD 1 are modularized to facilitate maintenance and replacement. The VFD 1 may be directly connected to a high-voltage cable, such as a 10 KV cable, to convert a frequency of the high-voltage cable into a frequency applicable to the permanent magnet motor 2. The permanent magnet motor 2 extends in an axial direction thereof to form a cylindrical structure, and may directly provide kinetic energy for a belt conveyor. The permanent magnet motor 2 adopts water cooling heat dissipation, and has the characteristics of low noise and low pollution during operation. The permanent magnet motor 2 adopts a 4-path winding input structure, which is matched with a multi-path output structure of the VFD 1 to reduce damage of VFD harmonics to insulation of a motor coil. A stator coil is composed of 4 three-phase branch coil windings connected in parallel. The permanent magnet motor 2 and the VFD 1 are assembled into an integrated machine, and the “integrated machine” in the following description refers to a permanent magnet motor 2 with the VFD 1. The power supply and distribution apparatus 3 may be selectively assembled on both left and right sides of the VFD 1 based on the field conditions to provide electric energy for the integrated machine and other electric devices. The integrated machine fitted with the power supply and distribution apparatus 3 can solve the problem of power supply for surrounding electric devices without a mobile substation, and cables can be installed for the surrounding electric devices one by one, which greatly reduces the installation cost of power supply cables in the integrated machine, reduces the construction difficulty and saving the construction time. Meanwhile, the permanent magnet and variable frequency integrated machine is small in size and convenient to install on site, so that the permanent magnet and variable frequency integrated machine can be descended into a well more smoothly while being convenient to move, and frequent relocation and face changes of the entry belt conveyor can be avoided.

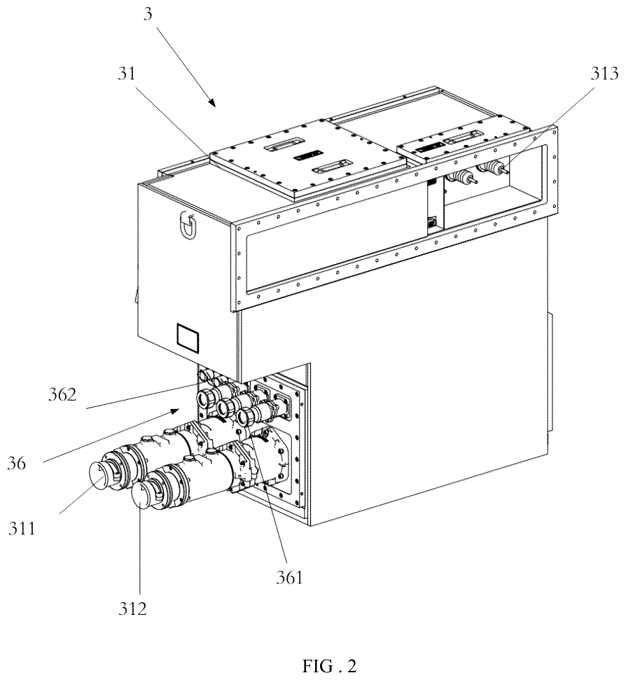

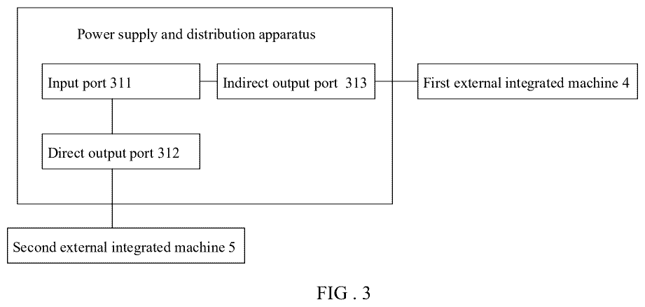

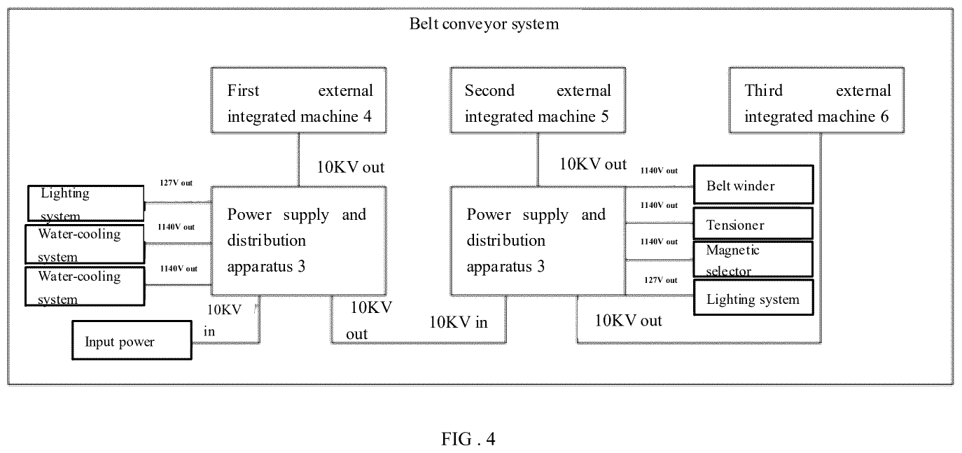

As shown in FIGS. 2 to 4, preferably, the power supply and distribution apparatus 3 includes a box body 31 and ports in the box body 31, the ports including an input port 311, a direct output port 312 and an indirect output port 313. The input port 311 is connected to a power connection. The direct output port 312 is electrically connected to the input port 311 and configured to directly output an input power. The indirect output port 313 is electrically connected to the input port 311 and connected to the permanent magnet motor 2 through the VFD 1.

Specifically, the input port 311 and the direct output port 312 are arranged side by side on a rear sidewall of the box body 31. The front and rear herein are based on an axial direction of the permanent magnet motor 2, and used for plugging external cables without affecting the assembly of the box body 31 to the integrated machine. To minimize the box body 31, the box body 31 has an inverted L shape, while the input port 311 and the direct output port 312 are provided in a vacancy of the inverted L shape to reduce occupation of the surrounding space. The input port 311 is used for plugging a cable for an input power, and the input port 311 and the direct output port 312 are directly connected through a wire in the box body 31. In other words, the input power enters the box body 31 through the input port 311, and then comes out from the direct output port 312 without any change in voltage. For example, if the input power is 10 KV, then the voltage input to the input port 311 is 10 KV, and the voltage output from direct output port 312 is also 10 KV. The direct output port 312 may be connected to the input port 311 of a next power supply and distribution apparatus 3, or may be connected to a second external integrated machine 5. The indirect output port 313 is disposed on a sidewall of the box body 31 close to the integrated machine, while the indirect output port 313 is connected to a first external integrated machine 4 to provide electric energy for the first external integrated machine 4. In other words, when a plurality of integrated machines are desired to be operated in series, only one 10 kV cable is led out from the input power and connected to the 10 kV input port 311 of the power supply and distribution apparatus 3 of one of the integrated machines, while the rest integrated machines may be connected in sequence through their 10 kV direct output ports 312, so that the indirect output ports 313 of the power supply and distribution apparatuses 3 supply power to the assembled integrated machines. For example, a belt conveyor system is typically configured with three belt conveyors, i.e., a first external integrated machine 4, a second external integrated machine 5 and a third external integrated machine 6. When the three integrated machines are required to supply power simultaneously, the power supply of nearby underground devices can be satisfied by configuring only the first external integrated machine 4 and the second external integrated machine 5 with power supply and distribution apparatuses 3, while the third external integrated machine 6 can be directly connected to the direct output port 312 of the power supply and distribution apparatus 3 of the second external integrated machine 5 without a separately configured power supply and distribution apparatus 3. Therefore, one apparatus is saved and the working efficiency is improved, while the failure rate is reduced.

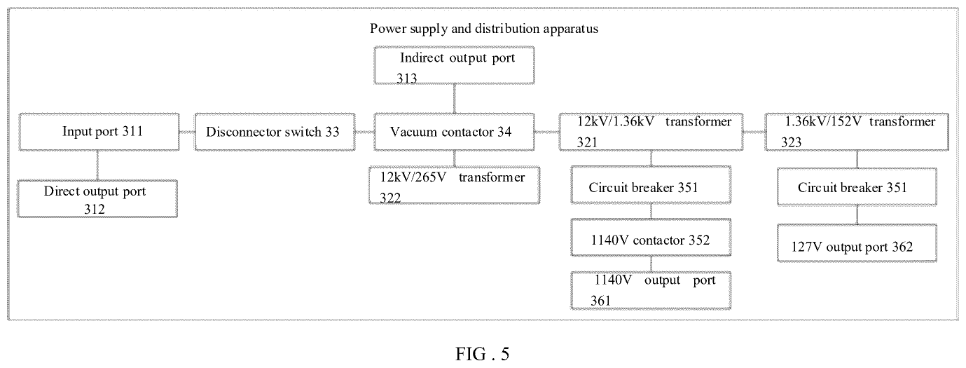

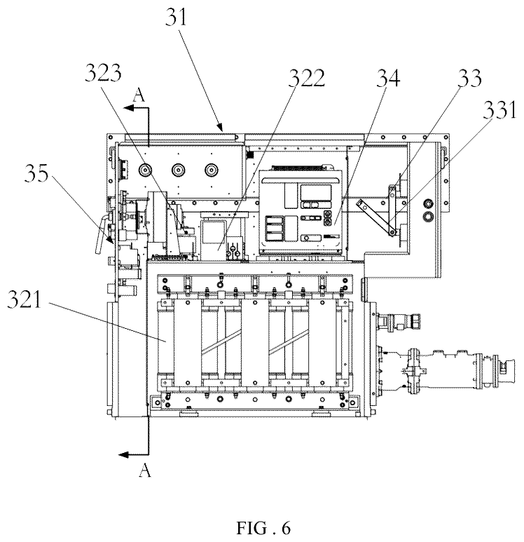

As shown in FIGS. 5 to 6, preferably, the power supply and distribution apparatus 3 includes multiple sets of transformers 32 electrically connected to the input port 311 and other electric devices to convert a voltage of the input power into voltages for the other electric devices.

Specifically, the multiple sets of transformers 32 are fixed in the box body 31, and include a 12 kV/1.36 kV transformer 321 for converting from 10 kV to 1140V, a 12 kV/265V transformer 322 for converting from 10 kV to 220V, and a 1.36 kV/ 152V transformer 323 for converting from 1140V to 127V. The 12 kV/1.36 kV transformer 321 and the 12 kV/265V transformer 322 are connected to a 10 KV input power through the input port 311, and the 1.36 kV/152V transformer 323 is connected to the 12 kV/1.36 kV transformer 321. The 12 kV/1.36 kV transformer 321 provides electric energy for a water-cooling system, a belt winder, a tensioner, a magnetic selector and the like in a belt conveyor system. The 12 kV/265V transformer 322 provides electric energy for internal structures of the power supply and distribution apparatus 3. The 1.36 kV/152V transformer 323 provides electric energy for a lighting system and the like. Therefore, the multiple sets of transformers 32 in the power supply and distribution apparatus 3 can not only provide electric energy for the integrated machine, but also provide computers for other devices in the belt conveyor system, thereby providing great convenience for underground power supply. Of course, other transformers may be provided, which is not limited here as long as they meet the requirement of underground power utilization.

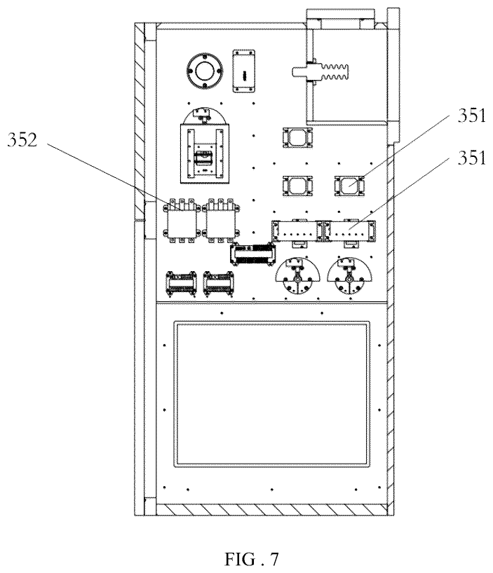

As shown in FIGS. 5 to 8, preferably, the power supply and distribution apparatus 3 is provided with a disconnector switch 33 and a vacuum contactor 34, and the multiple sets of transformers 32 and the indirect output port 313 are connected to the input port 311 through the disconnector switch 33 to disconnect a fault circuit.

Specifically, the input power enters the box body 31 through the input port 311, with one path directly output from the direct output port 312, and the other path connected to the disconnector switch 33 and the vacuum contactor 34, and then connected to the multiple sets of transformers 32 or the indirect output port 313. The disconnector switch 33 is a manual disconnector switch including a switch body 331 and an opening/closing gate 332. The switch body 331 is disposed in the box body, while the opening/closing gate 332 is disposed outside a sidewall of the box body 31. A switch state observation window 314 is disposed outside the sidewall of the box body 31 and used by the inspection and maintenance personnel to observe the opening and closing condition of the switch body 331 in the box body 31. The disconnector switch 33 may disconnect all circuits in the box body 31 except the circuit output from the direct output port 312. When the power supply and distribution apparatus 3 cannot function due to a fault, the power supply for a next integrated machine will not be affected. Of course, the power supply for the next integrated machine is still not influenced when the whole circuit is disconnected during maintenance, so that normal operation of the belt conveyor system is guaranteed, while the safety of the inspection and maintenance personnel is also ensured. The vacuum contactor 34 is an automatic switch which is automatically disconnected when the circuit has a fault. Such a design concept of double switches provides double protection for the power supply and distribution apparatus 3, the inspection and maintenance personnel and the belt conveyor system.

As shown in FIGS. 5 to 7, preferably, the power supply and distribution apparatus 3 is provided with a control element 35 configured to control a current at each voltage to enter the other electric devices.

Specifically, the control element 35 includes a circuit breaker 351 and a 1140V contactor 352, and is integrated on the sidewall of the box body 31. The circuit breaker 351 and the 1140V contactor 352 are both switches, where the circuit breaker 351 is a switch manually controlled by an operator, while the 1140V contactor 352 can be automatically opened when a short circuit occurs. The circuit breaker 351 and the 1140V contactor 352 are connected in series, the multiple sets of transformers 32 are connected to the electric devices through the circuit breakers 351 and the 1140V contactor 352 to control different power outputs. If any lines of a device fail, the failed lines may be cut off without affecting normal operation of other electric devices. The 1140V contactor 352 is disposed on an inner sidewall of the box body 31. Here, the 1140V contactor 352 of a circuit 1140 is provided and configured to protect the power supply and distribution apparatus 3 in case of a short circuit. A control body of the circuit breaker 351 is disposed on the inner sidewall of the box body 31, while operation buttons are disposed on an outer sidewall of the box body 31. As shown in FIG. 1, to facilitate operation of the operator, the sidewall here is preferably a rear sidewall of the power supply and distribution apparatus 3, and the operation buttons here may include a 3-way 1140V operation button 3511 for controlling 3 ways of 1140V power output; a 2-way 127V operation button 3512 for controlling 2 ways of 127V power output; and two 10 KV operation buttons 3513 for controlling outputs of the direct output port 312 and the indirect output port 313. The number of circuit breakers 351 may be determined according to the number of output powers, and is not limited herein. Each operation button has a flameproof structure meeting the class I explosion-proof requirements of coal mines.

As shown in FIG. 2, preferably, the power supply and distribution apparatus 3 further includes a plurality of output ports 36, via which the multiple sets of transformers 32 are connected to the other electric devices.

Specifically, the output ports 36 are regularly arranged at upper ends of the input port 311 and the direct output port 312, connected to the multiple sets of transformers 32, and serve as power output sockets. The output ports 36 may include a 1140V output port 361 and a 127V output port 362 for plugging external electrical devices. There may be more output ports 36 of course, which is not limited herein. The provision of the output ports 36 allows an operator to use the power supply and distribution apparatus 3 by simply remembering the plugging positions instead of long-time learning, thereby shortening the time for supplying power to surrounding electric devices by the power supply and distribution apparatus 3 on site and improving the working efficiency.

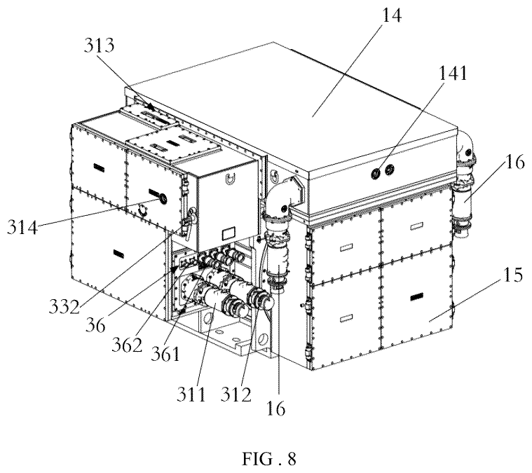

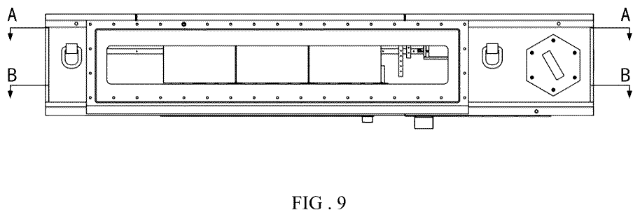

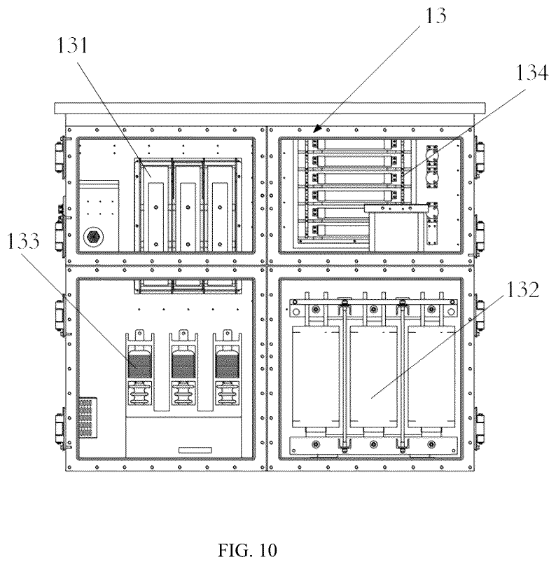

As shown in FIGS. 8 to 12, preferably, the VFD 1 includes a VFD module 11, a control module 12, and a protection module 13. The VFD module 11 is connected to the permanent magnet motor 2 and configured to convert a frequency of the input power into different frequencies to be output. The control module 12 disposed in an upper layer of the VFD module 11 to control the VFD module 11. The protection module 13 includes a fuse 131, a reactor 132 and a contactor 133, and is connected to the input power or the power supply and distribution apparatus 3, and configured to protect the VFD module 11.

Specifically, the VFD module 11, the control module 12 and the protection module 13 each adopt a modular design. The VFD module 11 and the control module 12 are disposed in the same VFD box 14, while the protection module 13 is disposed in a protection box 15 separately. The VFD box 14 is disposed on a peripheral side of the permanent magnet motor 2. The control module 12 is disposed in an upper layer of the VFD box 14 so that the device can be inspected and maintained simply by opening a cover. The VFD module 11 is disposed in a lower layer of the control module 12. A display screen 141 is disposed on a rear side the VFD box 14 to enable real-time display of a running state of the device. The protection box 15 is fitted around the VFD box 14. Here, the protection box 15 is fitted on the rear side the VFD box 14 to protect the VFD 1, including the fuse 131, the reactor 132, and the contactor 133, as well as a pre-charger 134 configured to supply power to the contactor 133. The power supply and distribution apparatus 3 is connected to the VFD 1 by firstly passing through the fuse 131, then the reactor 132, then the contactor 133, and finally into the VFD module 11, and then through the VFD module 11 into the permanent magnet motor 2. The various modularized parts facilitate on-site replacement and maintenance.

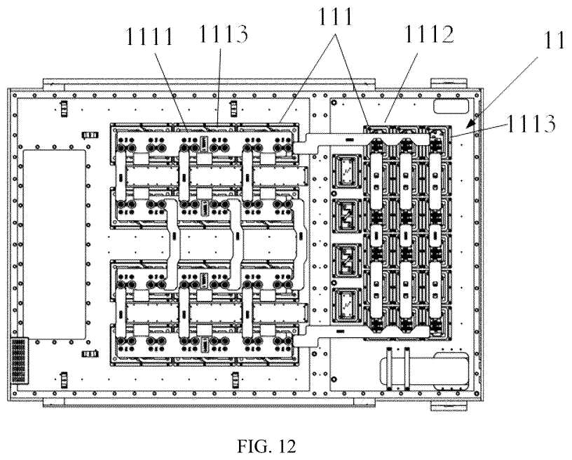

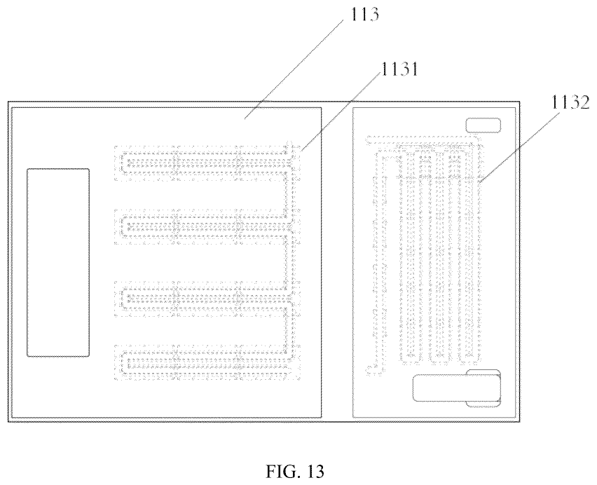

As shown in FIGS. 12 to 13, preferably, the VFD module 11 is disposed on a water-cooling heat dissipation plate 113 with an S-shaped heat dissipation water channel 1131.

Specifically, the VFD module 11 is an element with high heat generation, and the high heat generated during operation of the VFD module 11 may impair the working efficiency of the VFD 1. The VFD 1 needs to be cooled, and therefore, the water-cooling heat dissipation plate 113 with the S-shaped heat dissipation water channel 1131 is provided for heat dissipation, where cooling water in the water channel passes through a bottom of the heating module and takes away heat, thereby meeting the heat dissipation requirement of devices with high heat generation.

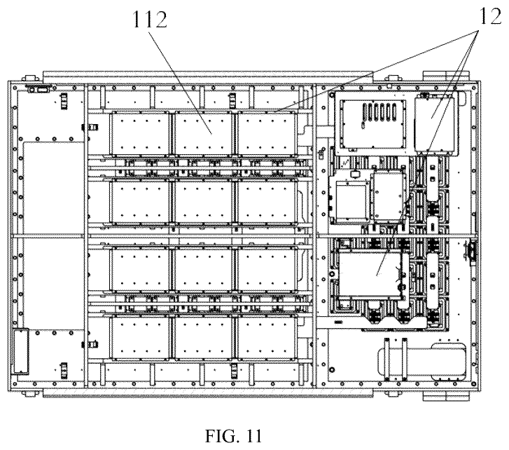

As shown in FIGS. 11 to 12, preferably, the VFD module 11 includes a power module 111 and a filter capacitor module 112 connected by a laminated busbar to reduce parasitic inductance.

Specifically, the power module 111 and the filter capacitor module 112 are directly connected by the VFD module 11 with a laminated busbar, so that parasitic inductance is smaller, and interference of the power busbar with the control circuit is effectively cut off. The power module 111 includes a rectifier module 1111 and an inverter module 1112 distributed on two sides of the water-cooling heat dissipation plate 113 and electrically connected to each other. The rectifier module 1111 is configured to convert alternating current into direct current, and is connected to the protection module 13. The inverter module 1112 is configured to convert direct current into alternating current, and is connected to the permanent magnet motor 2. Preferably, an insulation sheath 1113, which may be an insulation ceramic plate or insulation frame, is disposed outside the rectifier module 1111 and the inverter module 1112 to isolate a high-voltage power supply. The insulation ceramic plate is disposed at the bottom, while the insulation frame is arranged at the periphery, so that uniform heat dissipation of the power module 111 can be implemented, and local high-temperature explosion can be prevented.

As shown in FIG. 8, preferably, the VFD 1 includes at least one standby line inlet port 16 disposed on a sidewall of the VFD 1, connected to the protection module 13 and configured to connect the input power.

Specifically, the standby line inlet port 16 is disposed on a rear side of the VFD 1, and may be directly connected to the input power or the direct output port 312. As mentioned above, when three integrated machines are connected in series, only two of the integrated machines are required to be fitted with the power supply and distribution apparatus 3, while a third integrated machine only needs to be connected in series to the power supply and distribution apparatus 3 of either of the two integrated machines. The “connected in series” here refers to being connected in series through the standby line inlet port 16, and such a flexible connection mode can provide various power supply modes for the belt conveyor system and enable flexibility of on-site assembly.

Although various embodiments of the present disclosure have been shown and described herein, it will be obvious to those skilled in the art that such embodiments are provided by way of example only. Numerous modifications, changes, and substitutions may occur to those skilled in the art without departing from the spirit and scope of the present disclosure. It should be understood that various alternatives to the embodiments of the present disclosure described herein may be employed while practicing the present disclosure. It is intended that the following claims define the scope of the present disclosure and that equivalents or alternatives within the scope of these claims are covered thereby.

1. A permanent magnet and variable frequency integrated machine, comprising:
a variable-frequency drive (VFD) and a permanent magnet motor,
wherein the permanent magnet motor is configured to extend forwards and backwards in an axial direction thereof, and
the VFD is integrated on a peripheral side of the permanent magnet motor,
wherein a power supply and distribution apparatus, detachably connected to the VFD, is further provided on the peripheral side of the permanent magnet motor, and configured to provide electric energy for an electric device.

2. The permanent magnet and variable frequency integrated machine according to claim 1, wherein the power supply and distribution apparatus includes a box body and ports in the box body, the ports including:
an input port connected to a power connection;
a direct output port electrically connected to the input port and configured to directly output an input power; and
an indirect output port electrically connected to the input port and connected to the permanent magnet motor through the VFD.

3. The permanent magnet and variable frequency integrated machine according to claim 2, wherein the power supply and distribution apparatus is provided with multiple sets of transformers electrically connected to the input port and other electric devices to convert a voltage of the input power into voltages for the other electric devices.

4. The permanent magnet and variable frequency integrated machine according to claim 3, wherein the power supply and distribution apparatus is provided with a disconnector switch and a vacuum contactor, and the multiple sets of transformers and the indirect output port are connected to the input port through the disconnector switch and the vacuum contactor to disconnect a fault circuit.

5. The permanent magnet and variable frequency integrated machine according to claim 3, wherein the power supply and distribution apparatus is provided with a control element configured to control a current at the voltage to enter the other electric devices.

6. The permanent magnet and variable frequency integrated machine according to claim 3, wherein the power supply and distribution apparatus further includes a plurality of output ports, via which the multiple sets of transformers are connected to the other electric devices.

7. The permanent magnet and variable frequency integrated machine according to claim 2, wherein the VFD includes:
a VFD module connected to the permanent magnet motor and configured to convert a frequency of the input power into different frequencies to be output;
a control module disposed in an upper layer of the VFD module to control the VFD module; and
a protection module including a fuse, a reactor and a contactor, connected to the input power or the power supply and distribution apparatus, and configured to protect the VFD module.

8. The permanent magnet and variable frequency integrated machine according to claim 7, wherein the VFD module is disposed on a water-cooling heat dissipation plate with an S-shaped heat dissipation water channel.

9. The permanent magnet and variable frequency integrated machine according to claim 7, wherein the VFD module includes a power module and a filter capacitor module connected by a laminated busbar to reduce parasitic inductance.

10. The permanent magnet and variable frequency integrated machine according to claim 9, wherein the power module includes a rectifier module and an inverter module electrically connected with each other, the rectifier module is connected to the protection module, and the inverter module is connected to the permanent magnet motor.

11. The permanent magnet and variable frequency integrated machine according to claim 9, wherein the power module includes an insulation frame arranged around for isolating a high-voltage power supply and enabling uniform heat dissipation of the power module.

12. The permanent magnet and variable frequency integrated machine according to claim 7, wherein the VFD includes at least one standby line inlet port disposed on a sidewall of the VFD, connected to the protection module and configured to connect the input power.
